(19) United States
(12) Patent Application Publication
(10) Pub. No.: US 2025/0072265 A1
(43) Pub. Date: Feb. 27, 2025

(54) DISPLAY DEVICE

(71) Applicant: Samsung Display Co., Ltd., Yongin-si (KR)

(72) Inventors: MINSEOK KIM, Yongin-si (KR); SONGYI KIM, Yongin-si (KR); SUJIN KIM, Yongin-si (KR); DONG GYU BAECK, Yongin-si (KR); YONGSEOK CHOI, Yongin-si (KR)

(73) Assignee: Samsung Display Co., Ltd., Yongin-si (KR)

(21) Appl. No.: 18/660,685

(22) Filed: May 10, 2024

(30) Foreign Application Priority Data
Aug. 23, 2023 (KR) 10-2023-0110356

(51) Int. Cl. H10K 59/80; H10K 59/38

(52) U.S. Cl. CPC H10K 59/877; H10K 59/38

(57) ABSTRACT

A display device includes a display layer that provides source light, and a light control layer disposed on the display layer and including a plurality of light control parts distinguished from each other. At least one of the light control parts includes quantum dots that convert a wavelength of the source light, and plate-shaped scatterers made of layered double hydroxide to exhibit improved luminance and excellent display quality.

### CROSS-REFERENCE TO RELATED APPLICATIONS

This application claims priority to and benefits of Korean Patent Application No. 10-2023-0110356 under 35 U.S.C. § 119, filed on Aug. 23, 2023, in the Korean Intellectual Property Office (KIPO), the entire content of which are incorporated herein by reference.

### BACKGROUND

### 1. Technical Field

Embodiments of the disclosure described herein relate to a display device including a scatterer.

### 2. Description of the Related Art

A display device includes a transmissive display device that selectively transmits source light generated from a light source and a light-emissive display device that generates the source light from the display device itself. The display device may include different types of light control parts depending on pixels to generate a color image. The light control part may transmit only a portion of a wavelength range of the source light or change a color of the source light. Some light control parts may change characteristics of the light without changing the color of the source light.

A quantum dot material or the like is used in the light control part of the display device, and there is a need to develop a technology to increase an optical conversion efficiency or a light transmission efficiency in the light control part for improving a display quality of the display device.

### SUMMARY

Embodiments of the disclosure provide a display device with improved display quality by increasing a transmittance and a scattering effect of source light.

According to an embodiment, a display device may include a display layer that provides source light, and a light control layer disposed on the display layer and including a plurality of light control parts distinguished from each other. At least one of the plurality of light control parts may include quantum dots that convert a wavelength of the source light, and plate-shaped scatterers made of layered double hydroxide.

The plate-shaped scatterers may have a ratio of a maximum width of a surface and a thickness in a range of about 2:1 to about 10:1.

The maximum width may be in a range of about 5 nm to about 300 nm, and the thickness may be in a range of about 1 nm to about 50 nm.

The layered double hydroxide may be represented by Formula 1 below, in the Formula 1, M²⁺ may be Zn, Co, Mg, Mn, Ni, or Fe, M³⁺ may be Fe, Co, Ni, Al, Ga, or In, and X and Y may be independent of each other and greater than 0.

M²⁺_{X}M³⁺_{Y}(OH)_{(2X+3Y)} [Formula 1]

The plate-shaped scatterers may constitute in a range of about 0.1 wt % to about 20 wt % of a total weight 100 wt % of the plurality of light control parts including the plate-shaped scatterers.

The plurality of light control parts may include a red light control part that emits red light and includes first quantum dots and the plate-shaped scatterers, a green light control part that emits green light and includes second quantum dots and the plate-shaped scatterers, and a blue light control part that transmits the source light.

The blue light control part may include spherical scatterers.

The blue light control part may include the plate-shaped scatterers.

The source light may include blue light and green light.

The display layer may include a first electrode, a second electrode facing the first electrode, and a light-emitting portion disposed between the first electrode and the second electrode, and including a light-emitting element that emits the source light.

According to an embodiment, a display device may include a display panel that provides source light, and a light control panel disposed on the display panel and including an optical scattering layer including plate-shaped scatterers made of layered double hydroxide.

The plate-shaped scatterers may have a ratio of a maximum width or a surface and a thickness in a range of about 2:1 to about 10:1, the maximum width may be in a range of about 5 nm to about 300 nm, and the thickness may be in a range of about 1 nm to about 50 nm.

The plate-shaped scatterers may be represented by Formula 1 below, in the Formula 1, M²⁺ may be Zn, Co, Mg, Mn, Ni, or Fe, M³⁺ may be Fe, Co, Ni, Al, Ga, or In, and X and Y may be independent of each other and greater than 0.

M²⁺_{X}M³⁺_{Y}(OH)_{(2X+3Y)} [Formula 1]

The light control panel may further include a color filter layer disposed on the optical scattering layer and including a red filter, a green filter, and a blue filter, and the source light may be white light.

According to an embodiment, a display device divided into a first pixel area that emits red light, a second pixel area that emits green light, and a third pixel area that emits blue light on a plane may include a display panel including a light-emitting element, and a light control panel including a first light control part corresponding to the first pixel area, a second light control part corresponding to the second pixel area, and a third light control part corresponding to the third pixel area. The light control panel may be disposed on the display panel, the first light control part may include first quantum dots and plate-shaped scatterers, the second light control part may include second quantum dots and the plate-shaped scatterers, and the plate-shaped scatterers may be made of layered double hydroxide.

The plate-shaped scatterers may have a ratio of a maximum width of a surface and a thickness in a range of about 2:1 to about 10:1, the maximum width may be in a range of about 5 nm to about 300 nm, and the thickness may be in a range of about 1 nm to about 50 nm.

The plate-shaped scatterers may be represented by Formula 1 below, in the Formula 1, M²⁺ may be Zn, Co, Mg, Mn, Ni, or Fe, M³⁺ may be Fe, Co, Ni, Al, Ga, or In, and X and Y may be independent of each other and greater than 0.

M²⁺_{X}M³⁺_{Y}(OH)_{(2X+3Y)} [Formula 1]

The third light control part may include spherical scatterers and may not include the plate-shaped scatterers.

The light-emitting element may emit source light including the blue light and the green light.

The light control panel may further include a color filter layer spaced apart from the display panel and disposed on the light control layer, and the color filter layer may include a first color filter that is disposed corresponding to the first pixel area and transmits the red light, a second color filter that is disposed corresponding to the second pixel area and transmits the green light, and a third color filter that is disposed corresponding to the third pixel area and transmits the blue light.

### BRIEF DESCRIPTION OF THE FIGURES

The above and other objects and features of the disclosure will become apparent by describing in detail embodiments thereof with reference to the accompanying drawings.

FIG. 1 is a perspective view showing a display device according to an embodiment.

FIG. 2 is a schematic cross-sectional view showing a portion corresponding to line I-I′ in FIG. 1.

FIG. 3 is a plan view of a display panel according to an embodiment.

FIG. 4 is a plan view showing a portion of a display device according to an embodiment.

FIG. 5 is a schematic cross-sectional view of a display device according to an embodiment.

FIG. 6 is a schematic cross-sectional view of a light control layer according to an embodiment.

FIG. 7A is a perspective view of a conversion scatterer according to an embodiment.

FIG. 7B is a schematic diagram showing a portion of a conversion scatterer according to an embodiment.

FIG. 8 is a schematic cross-sectional view of a display device according to an embodiment.

FIG. 9A is a schematic diagram showing an emission form of light from a spherical scatterer according to an embodiment.

FIG. 9B is schematic a diagram showing an emission form of light from a plate-shaped scatterer according to an embodiment.

FIG. 10 is a graph showing wavelength characteristics of source light according to an embodiment.

FIG. 11A is a graph showing optical characteristics based on a wavelength in Comparative Example and Example.

FIG. 11B is a graph showing optical characteristics based on a wavelength in Comparative Example and Example.

FIG. 12 is a schematic cross-sectional view of a display device according to an embodiment.

### DETAILED DESCRIPTION

The disclosure may make various changes and may have various forms. Thus, specific embodiments will be illustrated in the drawings and will be described in detail in the text. However, this is not intended to limit the disclosure to a particular form of disclosure, and it should be understood to include all changes, equivalents, or substitutes included in the spirit and scope of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Like reference numerals refer to like components. In addition, in the drawings, thicknesses, ratios, and dimensions of components are exaggerated for effective description of technical content. “and/or” includes all of one or more combinations that the associated components may define.

Terms such as first, second, and the like may be used to describe various components, but the components should not be limited by the terms. The above terms are used only for the purpose of distinguishing one component from another. For example, without departing from the scope of the disclosure, a first component may be named as a second component, and similarly, the second component may also be named as the first component. The singular expression includes the plural expression unless the context clearly dictates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

As used herein, “group” refers to a group of the IUPAC periodic table.

As used herein, “group II” may include a group IIA element and a group IIB element. For example, the group II element may be magnesium (Mg) or zinc (Zn). However, the disclosure is not limited thereto.

As used herein, “group III” may include a group IIIA element and a group IIIB element. For example, the group III element may be aluminum (Al), indium (In), gallium (Ga), or titanium (Ti). However, the disclosure is not limited thereto.

As used herein, “group V” may include a group VA element and a group VB element. For example, a group V element may be phosphorus (P), arsenic (As), or antimony (Sb). However, the disclosure is not limited thereto.

As used herein, “group VI” may include a group VIA element and a group VIB element. For example, a group VI may be oxygen (O), sulfur(S), selenium (Se) or tellurium (Te). However, the disclosure is not limited thereto.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to one embodiment of the disclosure, and a method for manufacturing the display device according to one embodiment will be described with reference to the drawings.

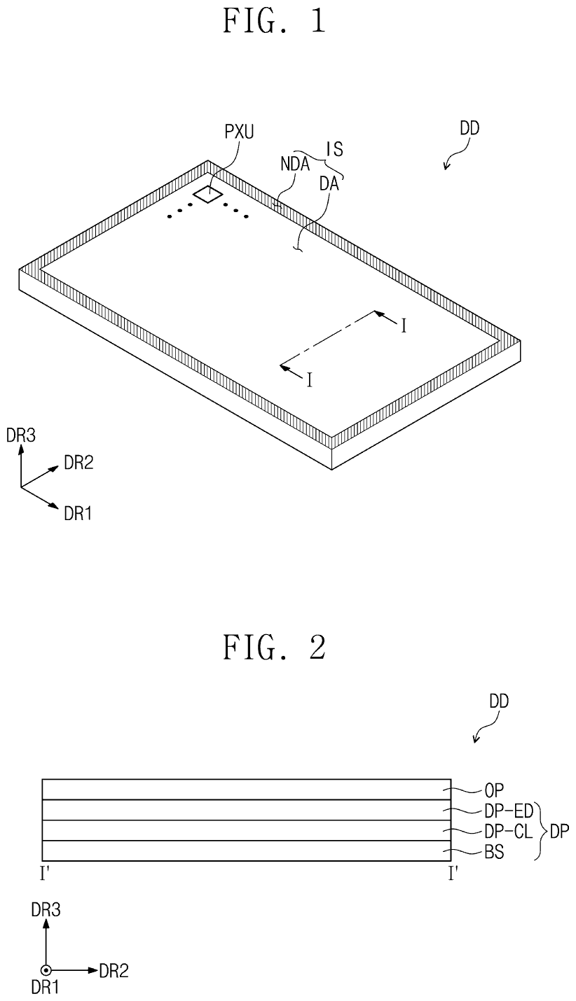

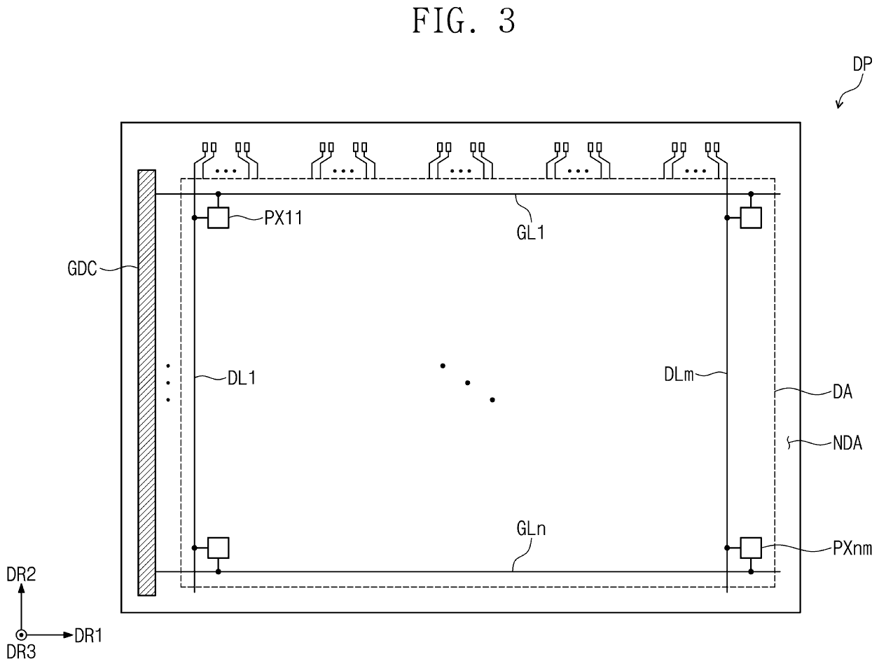

FIG. 1 is a perspective view showing a display device according to an embodiment. FIG. 2 is a schematic cross-sectional view of a display device according to an embodiment. FIG. 2 is a schematic cross-sectional view corresponding to line I-I′ in FIG. 1.

A display device DD in one embodiment may be a device that is activated in response to an electrical signal. For example, the display device DD may be a large device such as a television, a monitor, or an external billboard. The display device DD may be a small or medium-sized device such as a personal computer, a laptop computer, a personal digital terminal, a vehicle navigation unit, a game console, a smartphone, a tablet, and a camera. However, the disclosure is not limited thereto, and the display device DD may be employed as other electronic devices without deviating from the concept of the disclosure.

The display device DD may be rigid or flexible. The term “Flexible” refers to a property of being able to bend. For example, the flexible display device DD may include a curved device, a rollable device, or a foldable device.

FIG. 1 and drawings below illustrate first to third direction axes DR1 to DR3. Directions indicated by the first to third direction axes DR1, DR2, and DR3 described herein are relative concepts and are able to be converted to other directions. The directions indicated by the first to third direction axes DR1, DR2, and DR3 may be described as the first to third directions DR1, DR2, and DR3, and the same reference numerals may be used. Herein, the first direction axis DR1 and the second direction axis DR2 may be orthogonal to each other, and the third direction axis DR3 may be a normal direction to a plane defined by the first direction axis DR1 and the second direction axis DR2.

A thickness direction of the display device DD may be a direction parallel to the third direction axis DR3 that is the normal direction to the plane defined by the first direction axis DR1 and the second direction axis DR2. Herein, a front surface (or a top surface) and a rear surface (or a bottom surface) of members constituting the display device DD may be defined based on the third direction axis DR3. The front surface (or the top surface) and the rear surface (or the bottom surface) of each member constituting the display device DD may oppose each other in the third direction DR3, and a normal direction to each of the front and rear surfaces may be substantially parallel to the third direction DR3. A separation distance between the front surface and the rear surface defined along the third direction DR3 may correspond to a thickness of the member.

Herein, “on a plane” or “in a plan view” may be defined as a state viewed in the third direction DR3. Herein, “in a cross-section” or “in a cross-sectional view” may be defined as a state viewed in the first direction DR1 or the second direction DR2. The directions indicated by the first to third directions DR1, DR2, and DR3 are relative concepts and are able to be converted to other directions.

The display device DD may display an image (or a video) via a display surface IS. The display surface IS may include a plane defined by the first direction DR1 and the second direction DR2. The display surface IS may include a display area DA and a non-display area NDA. Multiple pixel units PXU may be disposed in the display area DA, and no pixel units PXU may be disposed in the non-display area NDA. The non-display area NDA may be defined along an edge of the display surface IS. The non-display area NDA may surround the display area DA. However, the disclosure may not be limited thereto. In one embodiment of the disclosure, the non-display area NDA may be omitted or may be placed only on a side of the display area DA.

The pixel units PXU may define pixel rows and pixel columns. The pixel unit PXU may be a minimum repeating unit. The pixel unit PXU may include at least one pixel. The pixel unit PXU may include multiple pixels that provide light of different colors.

In FIG. 1, the display device DD having the flat display surface IS is shown, but the disclosure is not limited thereto. In another embodiment, the display device DD may include a curved display surface or a three-dimensional display surface. The three-dimensional display surface may include multiple display areas directed in different directions.

Referring to FIG. 2, the display device DD according to one embodiment may include a display panel DP and a light control panel OP disposed on the display panel DP. The display panel DP may include a base layer BS, a circuit layer DP-CL, and a display layer DP-ED sequentially stacked in the direction indicated by the third direction axis DR3. The light control panel OP may be disposed on the display layer DP-ED. In one embodiment of the display device DD, the light control panel OP may be disposed directly on the display layer DP-ED.

Herein, a first component being “directly disposed/directly formed” on a second component may mean that a third component is not disposed between the first component and the second component. In other words, the first component being “directly disposed/directly formed” on the second component may mean that the first component is in “contact” with the second component.

Although not shown, in one embodiment, a charging layer (not shown) may be disposed between the display panel DP and the light control panel OP. The display panel DP and the light control panel OP may be spaced apart from each other with the charging layer (not shown) interposed between the display panel DP and the light control panel OP. The light control panel OP may be manufactured in a separate process step and provided on the display panel DP.

In one embodiment, the display panel DP may be referred to as a lower panel or a lower display substrate, and the light control panel OP may be referred to as an upper panel or an upper display substrate.

In the display device DD in one embodiment, the base layer BS may be a support substrate provided with the circuit layer DP-CL and the display layer DP-ED. The circuit layer DP-CL may include at least one insulating layer and a circuit element. The circuit element may include a signal line, a pixel driving circuit, and the like. The circuit layer DP-CL may be formed via a process of forming the insulating layer, a semiconductor layer, and a conductive layer via coating, deposition, and the like, and a patterning process of the insulating layer, the semiconductor layer, and the conductive layer via a photolithography process.

The display layer DP-ED may include a display element. The display element may include a light-emitting element that generates light and provides the light to the light control panel OP. The display panel DP including the display layer DP-ED may provide source light to the light control panel OP disposed on top of the display panel DP.

The light control panel OP may convert a wavelength of the light provided from the display panel DP or transmit a portion of the provided light. The light control panel OP may include a light control part that converts the wavelength of the light or transmits the light and structures to increase a conversion efficiency of the emitted light.

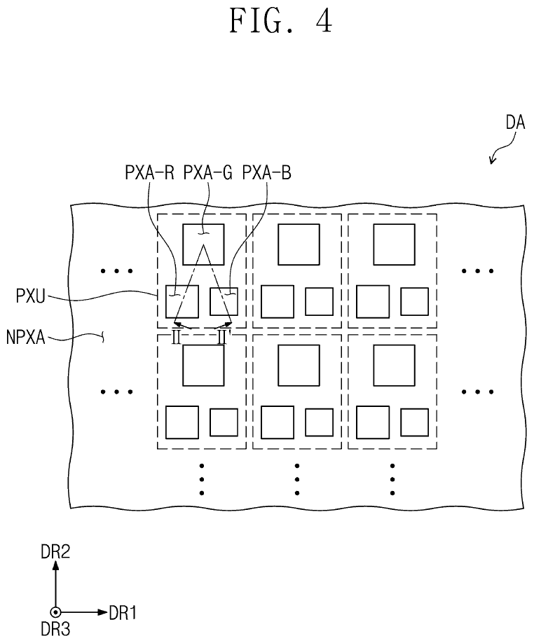

FIG. 3 is a plan view of a display panel according to an embodiment. FIG. 3 shows a planar arrangement relationship of signal lines GL1 to GLn and DL1 to DLm and pixels PX11 to PXnm. The signal lines GL1 to GLn and DL1 to DLm may include multiple gate lines GL1 to GLn and multiple data lines DL1 to DLm.

Each of the pixels PX11 to PXnm may be connected to a corresponding gate line among the gate lines GL1 to GLn and a corresponding data line among the data lines DL1 to DLm. Each of the pixels PX11 to PXnm may include a pixel driving circuit and a display element. Depending on a configuration of the pixel driving circuit of each of the pixels PX11 to PXnm, more types of signal lines may be disposed on the display panel DP.

Although FIG. 3 shows the pixels PX11 to PXnm in a matrix form as an embodiment, the disclosure is not limited thereto. In another embodiment, the pixels PX11 to PXnm may be arranged in a PENTILE™ form. For example, points where the pixels PX11 to PXnm are arranged may correspond to vertices of a diamond. A gate driving circuit GDC may be integrated into the display panel DP via an oxide silicon gate driver circuit (OSG) or amorphous silicon gate driver circuit (ASG) process.

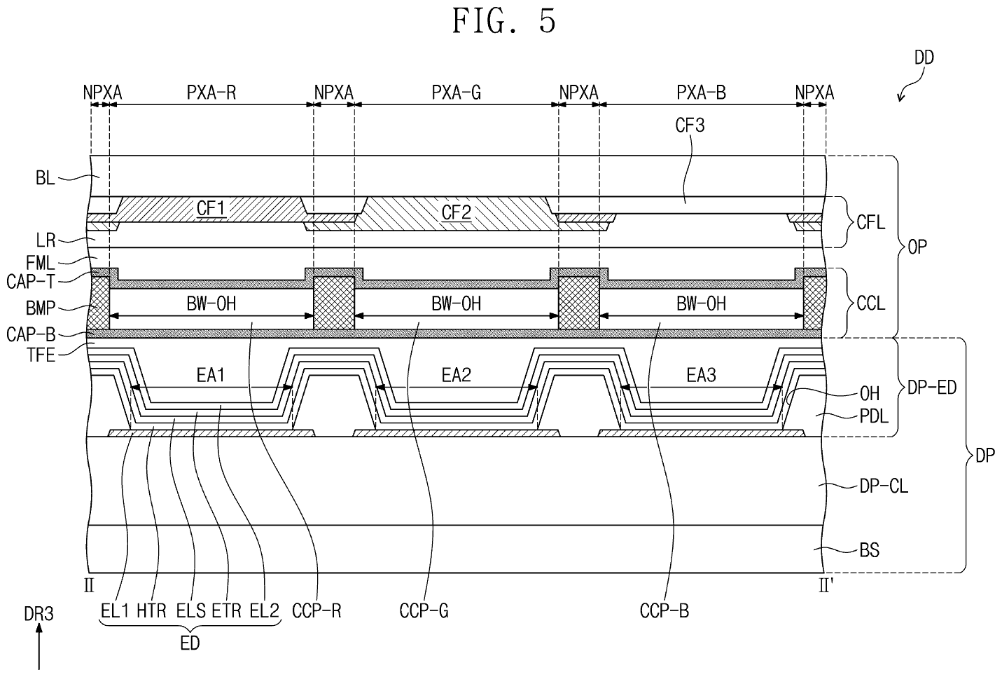

FIG. 4 is a plan view showing an enlarged portion of a display area in a display device according to an embodiment.

Referring to FIG. 4, in one embodiment, the pixel units PXU may be arranged in the first direction DR1 and the second direction DR2. In one embodiment, the pixel unit PXU may include a first pixel, a second pixel, and a third pixel that emit light in different wavelength ranges. Red light, green light, and blue light may be output from the first pixel, the second pixel, and the third pixel, respectively. In FIG. 4, a first pixel area PXA-R, a second pixel area PXA-G, and a third pixel area PXA-B respectively representing the first pixel, the second pixel, and the third pixel are shown. The first pixel area PXA-R may be an area where light generated from the first pixel is provided to the outside, the second pixel area PXA-G may be an area where light generated from the second pixel is provided to the outside, and the third pixel area PXA-B may be an area where light generated from the third pixel is provided to the outside. The first to third pixel areas PXA-R, PXA-G, and PXA-B may be distinguished from each other without overlapping each other in a plan view.

In one embodiment, the first pixel area PXA-R may be a red light-emitting area that emits the red light, the second pixel area PXA-G may be a green light-emitting area that emits the green light, and the third pixel area PXA-B may be a blue light-emitting area that emits the blue light. However, the disclosure is not limited thereto. In another embodiment, the display area DA may further include a pixel area that emits white light in addition to the first to third pixel areas PXA-R, PXA-G, and PXA-B.

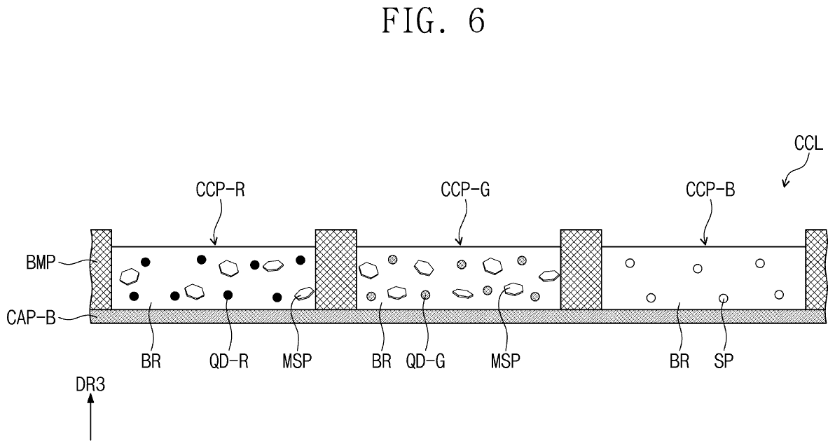

A peripheral area NPXA may be disposed to surround each of the first pixel area PXA-R, the second pixel area PXA-G, and the third pixel area PXA-B in a plan view. The peripheral area NPXA may be disposed between the first pixel area PXA-R, the second pixel area PXA-G, and the third pixel area PXA-B. The peripheral area NPXA may set boundaries of the first to third pixel areas PXA-R, PXA-G, and PXA-B, and prevent color mixing between the first to third pixel areas PXA-R, PXA-G, and PXA-B. In the peripheral area NPXA, a structure that prevents the color mixing between the first to third pixel areas PXA-R, PXA-G, and PXA-B, for example, a pixel defining layer PDL (FIG. 5), a split pattern BMP (FIG. 5), or the like may be disposed.

FIG. 4 shows the display device DD (FIG. 1) including the first to third pixel areas PXA-R, PXA-G, and PXA-B that have a same shape and have different area sizes in a plan view as an embodiment, but the disclosure is not limited thereto. In another embodiment, the area sizes of the first to third pixel areas PXA-R, PXA-G, and PXA-B may all be the same, or an area size of at least one type of pixel area may be different from area sizes of the remaining types of pixel areas. The area sizes of the first to third pixel areas PXA-R, PXA-G, and PXA-B may be set based on the colors of the emitted light.

Referring to FIG. 4, the first to third pixel areas PXA-R, PXA-G, and PXA-B may have a rectangular shape in a plan view. However, the disclosure is not limited thereto. The first to third pixel areas PXA-R, PXA-G, and PXA-B may have other polygonal shapes (including substantially polygonal shapes) such as a rhombus or pentagonal shape in a plan view. The first to third pixel areas PXA-R, PXA-G, and PXA-B may have a rectangular shape (a substantially rectangular shape) with rounded corners in a plan view.

FIG. 4 shows an embodiment that the second pixel area PXA-G is disposed in a first row and the first pixel area PXA-R and the third pixel area PXA-B are disposed in a second row, but the disclosure is not limited thereto. The arrangement of the first to third pixel areas PXA-R, PXA-G, and PXA-B may be changed in various ways. For example, the first to third pixel areas PXA-R, PXA-G, and PXA-B may be disposed in a same row.

The pixel areas PXA-R, PXA-G, and PXA-B may be aligned in a stripe shape, a PENTILE™ arrangement, or a Diamond Pixel™ arrangement. However, the disclosure is not limited thereto. An arrangement order and the arrangement form of the pixel areas PXA-R, PXA-G, and PXA-B may be provided in various combinations depending on characteristics of a display quality required for the display device DD (FIG. 1).

FIG. 5 is a schematic cross-sectional view showing a portion of a display device according to an embodiment. FIG. 5 may be a cross-sectional view showing a portion corresponding to line II-II′ in FIG. 4.

Referring to FIG. 5, in one embodiment, the display panel DP may include the base layer BS, the circuit layer DP-CL disposed on the base layer BS, and the display layer DP-ED disposed on the circuit layer DP-CL. The display layer DP-ED may include the pixel defining layer PDL, a light-emitting element ED, and an encapsulation layer TFE. The encapsulation layer TFE may cover the light-emitting element ED from above.

In the display device DD according to one embodiment, the display panel DP may be a light-emitting display panel. For example, the display panel DP may be an organic electroluminescent display panel. In case that the display panel DP is an organic electroluminescent display panel, the display layer DP-ED may include an organic electroluminescent light-emitting element as the light-emitting element ED. However, the disclosure is not limited thereto. For example, the display layer DP-ED may include a quantum dot light-emitting element as the light-emitting element ED. The display layer DP-ED may include a micro LED element and/or a nano LED element as the light-emitting element ED.

The display panel DP may provide the source light. The light-emitting element ED may generate the source light. The source light generated and output from the light-emitting element ED may be provided to the light control panel OP, and at least a portion of the source light may be optically converted into light with a wavelength different from a wavelength of the source light or at least a portion of the source light may be transmitted without the wavelength conversion in a light control layer CCL of the light control panel OP.

In the display panel DP, the base layer BS may be a member that provides a base surface on which the circuit layer DP-CL and the display layer DP-ED are disposed. The base layer BS may be a glass substrate, a metal substrate, a polymer substrate, or the like. However, the disclosure is not limited thereto, and the base layer BS may be an inorganic layer, a functional layer, or a composite material layer.

The base layer BS may have a multi-layer structure. For example, the base layer BS may have a three-layer structure of a polymer resin layer, an adhesive layer, and a polymer resin layer. For example, the polymer resin layer may contain a polyimide-based resin. In another embodiment, the polymer resin layer may contain at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. An “α-based” resin may mean a resin containing a functional group of the “a”.

The circuit layer DP-CL may be disposed on the base layer BS. The circuit layer DP-CL may include an insulating layer, a semiconductor pattern, a conductive pattern, a signal line, and the like. The insulating layer, the semiconductor layer, and the conductive layer may be formed on the base layer BS via coating, deposition, or the like, and the insulating layer, the semiconductor layer, and the conductive layer may be selectively patterned via multiple times of photolithography processes. Thereafter, the semiconductor pattern, the conductive pattern, and the signal line included in the circuit layer DP-CL may be formed. In one embodiment, the circuit layer DP-CL may include a transistor, a buffer layer, and multiple insulating layers. In one embodiment, the circuit layer DP-CL may include multiple transistors (not shown). Each of the transistors (not shown) may include a control electrode, an input electrode, and an output electrode. For example, the circuit layer DP-CL may include a switching transistor and a driving transistor for driving the light-emitting element ED of the display layer DP-ED.

The display layer DP-ED may include a light-emitting element ED as the display element. The light-emitting element ED may generate the source light. In one embodiment, the source light may include the blue light and the green light. In another embodiment, the source light may be the white light, and the source light may include the blue light, the green light, and the red light. In another embodiment, the source light may include only light in a blue light wavelength range.

In one embodiment, the display layer DP-ED may include the light-emitting element ED including a first electrode EL1, a second electrode EL2 facing the first electrode EL1, and a light-emitting portion ELS disposed between the first electrode EL1 and the second electrode EL2. In one embodiment, the light-emitting portion ELS may contain an organic light-emitting material, and the light-emitting element ED may be an organic electroluminescent light-emitting element. The light-emitting element ED may further include a hole transport region HTR and an electron transport region ETR. Although not shown, the light-emitting element ED may further include a capping layer (not shown) disposed on top of the second electrode EL2.

The display layer DP-ED may include the pixel defining layer PDL. The pixel defining layer PDL may be disposed on the circuit layer DP-CL and cover a portion of the first electrode EL1. A light-emitting opening OH may be defined in the pixel defining layer PDL. The light-emitting opening OH of the pixel defining layer PDL may expose at least a portion of the first electrode EL1. In an embodiment, light-emitting areas EA1, EA2, and EA3 may be defined to correspond to partial areas of the first electrode EL1 exposed by the light-emitting opening OH.

The pixel defining layer PDL may be made of a polymer resin. For example, the pixel defining layer PDL may include a polyacrylate-based resin or a polyimide-based resin. The pixel defining layer PDL may further include an inorganic material in addition to the polymer resin. In one embodiment, the pixel defining layer PDL may include a light-absorbing material, a black pigment, or a black dye. The pixel defining layer PDL including the black pigment or the black dye may implement a black pixel defining layer. When forming the pixel defining layer PDL, carbon black or the like may be used as the black pigment or the black dye, but the disclosure is not limited thereto.

The pixel defining layer PDL may be made of an inorganic material. For example, the pixel defining layer PDL may be made of an inorganic material such as silicon nitride (SiNₓ), silicon oxide (SiOₓ), and silicon oxynitride (SiOₓN_{y}).

The display panel DP may include the first light-emitting area EA1, the second light-emitting area EA2, and the third light-emitting area EA3. The first light-emitting area EA1, the second light-emitting area EA2, and the third light-emitting area EA3 may be areas divided by the pixel defining layer PDL. The first light-emitting area EA1, the second light-emitting area EA2, and the third light-emitting area EA3 may correspond to the first pixel area PXA-R, the second pixel area PXA-G, and the third pixel area PXA-B, respectively. Herein, the term “correspond to” may mean that two components overlap each other in the thickness direction DR3 of the display device DD and the components are not limited to have the same area size.

The light-emitting areas EA1, EA2, and EA3 may overlap the pixel areas PXA-R, PXA-G, and PXA-B in the thickness direction DR3, respectively. In a plan view, area sizes of the pixel areas PXA-R, PXA-G, and PXA-B divided from each other by the split pattern BMP may be greater than area sizes of the light-emitting areas EA1, EA2, and EA3 divided from each other by the pixel defining layer PDL.

In the light-emitting element ED, the first electrode EL1 may be disposed on the circuit layer DP-CL. The first electrode EL1 may be exposed at the light-emitting opening OH of the pixel defining layer PDL. The first electrode EL1 may be an anode or a cathode. The first electrode EL1 may be a pixel electrode. The first electrode EL1 may be a transmissive electrode, a semi-transmissive electrode, or a reflective electrode.

The second electrode EL2 may be disposed on the first electrode EL1. The second electrode EL2 may be a cathode or an anode. In one embodiment, in case that the first electrode EL1 is the anode, the second electrode EL2 may be the cathode, and in case that the first electrode EL1 is the cathode, the second electrode EL2 may be the anode. The second electrode EL2 may be a common electrode. However, the disclosure is not limited thereto. The second electrode EL2 may be a transmissive electrode, a semi-transmissive electrode, or a reflective electrode.

In one embodiment, the light-emitting portion ELS may be provided as a single light-emitting layer or as a light-emitting stack in which multiple light-emitting units are stacked each other. In case that the light-emitting portion ELS is a light-emitting stack in which the light-emitting units are stacked each other, the light-emitting portion ELS may include two or more light-emitting stacks that are distinguished from each other and stacked in the third direction DR3, which is the thickness direction. Each of the light-emitting units may include at least one light-emitting layer.

For example, in one embodiment, the light-emitting portion ELS may include at least one blue light-emitting unit that emits the blue light and at least one green light-emitting unit that emits the green light. The light-emitting portion ELS may include a charge generating layer disposed between the light-emitting units. However, the disclosure is not limited thereto, and the light-emitting portion ELS may include the blue light-emitting unit that emits the blue light, the green light-emitting unit that emits the green light, and a red light-emitting unit that emits the red light. In another embodiment, the light-emitting portion ELS may include multiple light-emitting units that emit light in the same wavelength area.

The light-emitting layer included in the light-emitting portion ELS may have a single layer made of a single material, a single layer made of different materials, or a multi-layer structure having multiple layers made of different materials. The light-emitting layer may contain a fluorescent or phosphorescent material. In the light-emitting element ED in one embodiment, the light-emitting portion ELS may contain an organic light-emitting material, an organic metal complex, a quantum dot, or the like as a light-emitting material.

The light-emitting portion ELS may be commonly disposed in the first to third light-emitting areas EA1, EA2, and EA3 and a non-light-emitting area. The non-light-emitting area may be a portion that overlaps the pixel defining layer PDL in the thickness direction DR3. However, the disclosure is not limited thereto. In one embodiment, the light-emitting portion ELS may be disposed in the light-emitting opening OH. For example, the light-emitting portion ELS may be disposed to be separated such that separated portions thereof respectively correspond to the first to third light-emitting areas EA1, EA2, and EA3 divided by the pixel defining layer PDL.

In the light-emitting element ED, the hole transport region HTR may be disposed on the first electrode EL1. The hole transport region HTR may be commonly disposed in the first to third light-emitting areas EA1, EA2, and EA3 and the non-light-emitting area. In one embodiment, the hole transport region HTR may overlap the multiple pixel units PXU of the display area DA shown in FIG. 4 as a common layer in the thickness direction DR3. However, the disclosure is not limited thereto, and the hole transport region HTR may be disposed to be separated such that separated portions thereof respectively correspond to the first to third light-emitting areas EA1, EA2, and EA3. The hole transport region HTR may include at least one of a hole transport layer, a hole injection layer, and an electron blocking layer.

The electron transport region ETR may be disposed on the light-emitting portion ELS. The electron transport region ETR may include at least one of an electron injection layer, an electron transport layer, and a hole blocking layer. The electron transport region ETR may be commonly disposed in the first to third light-emitting areas EA1, EA2, and EA3 and the non-light-emitting area. However, the disclosure is not limited thereto, and the electron transport region ETR may be disposed to be separated such that separated portions thereof respectively correspond to the first to third light-emitting areas EA1, EA2, and EA3.

The encapsulation layer TFE may be disposed on the second electrode EL2. In another embodiment, in case that the light-emitting element ED includes a capping layer (not shown), the encapsulation layer TFE may be disposed on the capping layer (not shown). The encapsulation layer TFE may cover the light-emitting element ED.

The encapsulation layer TFE may be a thin film encapsulation layer. The encapsulation layer TFE may be a single layer or a stack of multiple layers. The encapsulation layer TFE may include at least one insulating layer. The encapsulation layer TFE according to one embodiment may include at least one inorganic film (hereinafter, referred to as an encapsulation inorganic film). In another embodiment, the encapsulation layer TFE according to one embodiment may include at least one organic film (hereinafter, referred to as an encapsulation organic film) and the at least one encapsulation inorganic film.

The encapsulation inorganic film may protect the light-emitting element ED from moisture/oxygen, and the encapsulation organic film may protect the light-emitting element ED from foreign substances such as dust particles. The encapsulation inorganic film may contain silicon nitride, silicon oxy nitride, silicon oxide, titanium oxide, aluminum oxide, or the like, but the disclosure is not particularly limited thereto. The encapsulation organic film may contain an acrylic compound, an epoxy compound, or the like. The encapsulation organic film may contain a photopolymerizable organic material, but the disclosure is not particularly limited thereto.

The light control panel OP may be disposed on the display panel DP. In the display device DD in one embodiment shown in FIG. 5, the light control panel OP may be disposed directly on the display panel DP. However, the disclosure is not limited thereto, and the display device DD may include a charging layer (not shown) disposed between the display panel DP that is the lower panel and the light control panel OP that is the upper panel, as described above.

In one embodiment, the light control panel OP may include the light control layer CCL. In one embodiment shown in FIG. 5, the light control layer CCL may be disposed on the encapsulation layer TFE. In one embodiment, the light control panel OP may include a low refractive index layer LR, a color filter layer CFL, and a base substrate BL in addition to the light control layer CCL.

In one embodiment, the light control layer CCL may contain quantum dots. The light control layer CCL may include multiple light control parts CCP-R, CCP-G, and CCP-B. At least one of the first to third light control parts CCP-R, CCP-G, and CCP-B may contain the quantum dots that convert optical properties of the source light.

The light control layer CCL may include the split pattern BMP. The split pattern BMP may be a component that distinguishes the light control parts CCP-R, CCP-G, and CCP-B from each other. The split pattern BMP may contain a base resin and an additive. The base resin may be made of various resin compositions, which may generally be referred to as binders. The additive may include a coupling agent and/or a photoinitiator. The additive may further include a dispersant.

The split pattern BMP may contain a black coloring agent for light blocking. The split pattern BMP may contain a black dye or a black pigment mixed into the base resin. In one embodiment, the split pattern BMP may contain carbon black or may include metals such as chromium or oxides thereof.

In the split pattern BMP, an opening BW-OH corresponding to the light-emitting opening OH may be defined. In a plan view, the opening BW-OH may overlap the light-emitting opening OH and has an area size greater than an area size of the light-emitting opening OH. For example, the opening BW-OH may have a greater area size than the light-emitting areas EA1, EA2, and EA3 defined by the light-emitting opening OH. The light control parts CCP-R, CCP-G, and CCP-B may be disposed inside the opening BW-OH.

In one embodiment, the light control layer CCL may include the first light control part CCP-R corresponding to the first pixel area PXA-R, the second light control part CCP-G corresponding to the second pixel area PXA-G, and the third light control part CCP-B corresponding to the third pixel area PXA-B. The first light control part CCP-R may be a red light control part that emits the red light, and the second light control part CCP-G may be a green light control part that emits the green light. The third light control part CCP-B may be a blue light control part that emits the blue light. In another embodiment, the third light control part CCP-B may be a transmissive light control part that transmits and emits the source light.

In the light control panel OP according to one embodiment shown in FIG. 5, the base substrate BL may be a member that provides a reference surface on which the color filter layer CFL, the low refractive index layer LR, the light control layer CCL, and the like are disposed. The base substrate BL may be a glass substrate, a metal substrate, a plastic substrate, or the like. However, the disclosure is not limited thereto, and the base substrate BL may be an inorganic layer, an organic layer, or a composite material layer. In another embodiment, the base substrate BL may be omitted.

Although not shown, an anti-reflection layer may be disposed on the base substrate BL. The anti-reflection layer may be a layer that reduces a reflectance of external light incident from the outside. The anti-reflection layer may be a layer that selectively transmits light emitted from the display device DD. In one embodiment, the anti-reflection layer may be a single layer containing a dye and/or a pigment dispersed in a base resin. The anti-reflection layer may be provided as one continuous layer entirely overlapping all of the first to third pixel areas PXA-R, PXA-G, and PXA-B in the thickness direction DR3.

The anti-reflection layer may not include a polarizing layer. Accordingly, the light passing through the anti-reflection layer and incident on the display layer DP-ED may be unpolarized light. The display layer DP-ED may receive the unpolarized light from above the anti-reflection layer.

In one embodiment, the light control layer CCL may include barrier layers CAP-B and CAP-T. The barrier layers CAP-B and CAP-T may prevent penetration of the moisture and/or the oxygen (hereinafter, referred to as the ‘moisture/oxygen’) and adjust a refractive index to improve optical properties of the light control panel OP. The barrier layers CAP-B and CAP-T may be disposed at an upper portion or a lower portion of the light control layer CCL. The barrier layers CAP-B and CAP-T may be disposed on top surfaces or bottom surfaces of the light control parts CCP-R, CCP-G, and CCP-B to block exposure of the light control parts CCP-R, CCP-G, and CCP-B to the moisture/oxygen, for example, block exposure of the quantum dots contained in the light control parts CCP-R, CCP-G, and CCP-B to the moisture/oxygen. The barrier layers CAP-B and CAP-T may also protect the light control parts CCP-R, CCP-G, and CCP-B from an external impact.

In one embodiment, the first barrier layer CAP-T may be spaced apart from the display layer DP-ED with the light control parts CCP-R, CCP-G, and CCP-B interposed between the first barrier layer CAP-T and the display layer DP-ED. For example, the first barrier layer CAP-T may be disposed on the top surfaces of the light control parts CCP-R, CCP-G, and CCP-B. In one embodiment, the light control layer CCL may further include the second barrier layer CAP-B disposed between the light control parts CCP-R, CCP-G, and CCP-B and the display layer DP-ED. In one embodiment, the first barrier layer CAP-T may cover the top surfaces of the light control parts CCP-R, CCP-G, and CCP-B adjacent to the low refractive index layer LR, and the second barrier layer CAP-B may cover the bottom surfaces of the light control parts CCP-R, CCP-G, and CCP-B adjacent to the display layer DP-ED. The “top surface” may be a surface located above in the third direction DR3, and the “bottom surface” may be a surface located below in the third direction DR3.

The first barrier layer CAP-T and the second barrier layer CAP-B may cover a surface of the split pattern BMP as well as the light control parts CCP-R, CCP-G, and CCP-B.

The first barrier layer CAP-T may cover a surface of each of the split pattern BMP and the light control parts CCP-R, CCP-G, and CCP-B adjacent to the low refractive index layer LR. The first barrier layer CAP-T may be disposed to follow steps of the split pattern BMP and the light control parts CCP-R, CCP-G, and CCP-B.

The first barrier layer CAP-T and the second barrier layer CAP-B may include an inorganic material. In one embodiment, the first barrier layer CAP-T may include silicon oxynitride (SiON). Both the first barrier layer CAP-T and the second barrier layer CAP-B may include silicon oxynitride. However, without being limited thereto, the first barrier layer CAP-T may include silicon oxynitride, and the second barrier layer CAP-B may include silicon oxide (SiOₓ).

The light control panel OP may further include the color filter layer CFL disposed on the light control layer CCL. The color filter layer CFL may include one or more color filters CF1, CF2, and CF3. The color filter may transmit light in a specific wavelength range and block light in a wavelength range outside of the corresponding wavelength range. In one embodiment, the first color filter CF1 may be a red filter that transmits the red light, the second color filter CF2 may be a green filter that transmits the green light, and the third color filter CF3 may be a blue filter that transmits the blue light.

Each of the color filters CF1, CF2, and CF3 may contain a polymer photosensitive resin and a colorant. The colorant may include a pigment or a dye. The first color filter CF1 may contain a red pigment or a red dye, the second color filter CF2 may contain a green pigment or a green dye, and the third color filter CF3 may contain a blue pigment or a blue dye. In one embodiment, the third color filter CF3 may not contain the pigment or the dye.

The first to third color filters CF1, CF2, and CF3 may be arranged to correspond to the first pixel area PXA-R, the second pixel area PXA-G, and the third pixel area PXA-B, respectively. The first to third color filters CF1, CF2, and CF3 may overlap the first to third light control parts CCP-R, CCP-G, and CCP-B in the thickness direction DR3, respectively.

Referring to FIG. 5, the color filters CF1, CF2, and CF3 that transmit light of different colors may be arranged to overlap each other in the peripheral area NPXA. As the color filters CF1, CF2, and CF3 are arranged to overlap each other in the third direction DR3, which is the thickness direction, in the peripheral area NPXA, boundaries of the adjacent pixel areas PXA-R, PXA-G, and PXA-B may be distinguished. In another embodiment, the color filter layer CFL may include a light blocking portion (not shown) to distinguish the boundaries between the adjacent color filters CF1, CF2, and CF3. The light blocking portion (not shown) may be formed of a blue filter or may be made of an organic light blocking material or an inorganic light blocking material containing a black pigment or a black dye.

Referring to FIG. 5, in one embodiment, the light control panel OP may further include the low refractive index layer LR. The low refractive index layer LR may be disposed between the light control layer CCL and the color filters CF1, CF2, and CF3. The low refractive index layer LR may be disposed between the light control parts CCP-R, CCP-G, and CCP-B and the color filters CF1, CF2, and CF3 and perform functions of an optical functional layer such as increasing a light extraction efficiency of the light emitted from the light control layer CCL or preventing reflected light from entering the light control layer CCL. The low refractive index layer LR may be a layer with a relatively low refractive index compared to the adjacent layers.

The low refractive index layer LR may include at least one inorganic layer. For example, the low refractive index layer LR may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film with light transmittance. However, the disclosure is not limited thereto, and the low refractive index layer LR may include an organic film. For example, the low refractive index layer LR may have a structure in which multiple hollow particles are dispersed in an organic polymer resin. The low refractive index layer LR may be composed of a single layer or multiple layers.

In one embodiment, the light control panel OP may further include a buffer layer FML. In one embodiment, the buffer layer FML may fill a space between the light control layer CCL and the color filter layer CFL.

The buffer layer FML may function as a buffer between the light control layer CCL and the color filter layer CFL. In one embodiment, the buffer layer FML may function as an impact absorber or the like and increase a strength of the display device DD. The buffer layer FML may function as a protective layer that protects the light control layer CCL.

The buffer layer FML may be formed from a filling resin including a polymer resin. For example, the buffer layer FML may be formed from a filling resin including an acrylate-based resin or an epoxy resin. In another embodiment, the buffer layer FML may be an inorganic layer containing at least one inorganic material such as silicon nitride, silicon oxide, and silicon oxynitride. The buffer layer FML may be composed of a single layer or multiple layers. In another embodiment, the buffer layer FML may be omitted, and the color filter layer CFL may be disposed directly on the light control layer CCL.

In one embodiment, although not shown, the light control panel OP may further include a scattering layer. The scattering layer may include a plate-shaped scatterer to be described below. The scattering layer may disperse the light emitted from the display layer DP-ED and provide the dispersed light to the light control layer CCL. In another embodiment, the scattering layer may be disposed on top of the light control layer CCL and disperse the light emitted from the light control layer CCL.

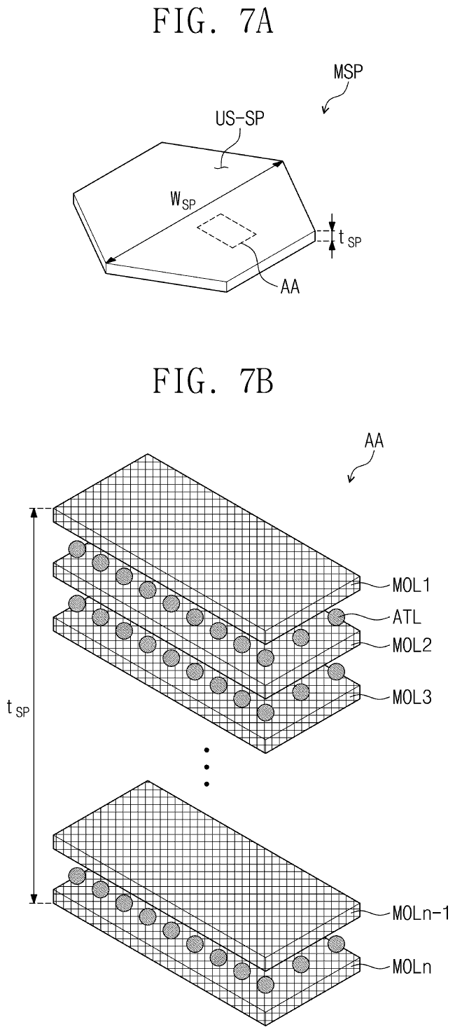

FIG. 6 is a schematic cross-sectional view showing a portion of a light control layer according to an embodiment. The light control layer CCL in one embodiment may include the first light control part CCP-R, the second light control part CCP-G, and the third light control part CCP-B separated from each other by the split pattern BMP. In one embodiment, at least one of the light control parts CCP-R, CCP-G, and CCP-B may contain a plate-shaped scatterer MSP. The plate-shaped scatterer MSP may have a plate shape where a width of a top surface or a bottom surface is greater than a thickness. The plate-shaped scatterer MSP may have a thickness and a width ranging from a few nanometers (nm) to hundreds of nm. The plate-shaped scatterer MSP may also be named a nanoplate scatterer.

In one embodiment, the first light control part CCP-R corresponding to the first pixel area PXA-R (FIG. 5), which is a red pixel area, may contain first quantum dots QD-R, and the second light control part CCP-G corresponding to the second pixel area PXA-G (FIG. 5), which is a green pixel area, may contain second quantum dots QD-G. The first light control part CCP-R and the second light control part CCP-G may respectively contain base resins BR, and may respectively have the first quantum dots QD-R and the second quantum dots QD-G dispersed in the base resins BR.

In one embodiment, at least one of the first light control part CCP-R and the second light control part CCP-G may include the plate-shaped scatterers MSP. In one embodiment, only the second light control part CCP-G may include the plate-shaped scatterers MSP, or both the first and second light control parts CCP-R and CCP-G may include the plate-shaped scatterers MSP. The plate-shaped scatterers MSP may be dispersed in the base resin BR.

The plate-shaped scatterer MSP may be made of layered double hydroxide. In one embodiment, the plate-shaped scatterer MSP may contain the layered hydroxide, which is a compound represented by Formula 1 below.

M²⁺_{X}M³⁺_{Y}(OH)_{(2X+3Y)} [Formula 1]

In Formula 1, M²⁺ may be a divalent metal ion and M³⁺ may be a trivalent metal ion. In one embodiment, M²⁺ may be Zn, Co, Mg, Mn, Ni, or Fe, and M³⁺ may be Fe, Co, Ni, Al, Ga, or In. In Formula 1, each of X and Y may be greater than 0.

In one embodiment, the plate-shaped scatterer MSP may be made of hydroxide of a divalent metal ion and a trivalent metal ion. In the layered double hydroxide represented by Formula 1, Zn, Mg, or Mn may be included as the divalent ion, Al, Ga, or In may be included as the trivalent ion, and Fe, Co, or Ni may be included as the divalent ion or the trivalent ion. For example, in one embodiment, the plate-shaped scatterer MSP may be Mg₂Al(OH)₇. However, the disclosure is not limited thereto.

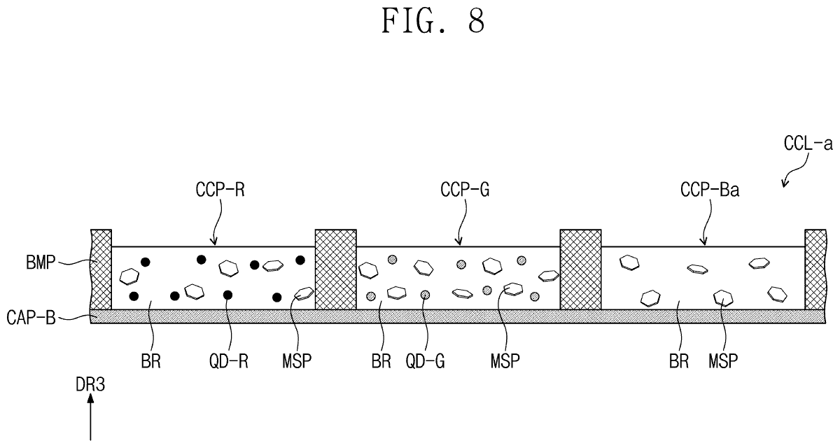

FIGS. 7A and 7B are schematic diagrams showing a plate-shaped scatterer according to an embodiment. FIG. 7A shows a perspective view of a plate-shaped scatterer according to an embodiment, and FIG. 7B is a schematic diagram showing a configuration of a portion of a plate-shaped scatterer according to an embodiment. FIG. 7B may be an enlarged view of area “AA” in FIG. 7A.

Referring to FIG. 7A, the plate-shaped scatterer MSP according to one embodiment may have a plate-shaped shape with a maximum width W_{SP} in a plan view significantly greater than a thickness tsp. The maximum width in a plan view W_{SP} may correspond to a maximum width on a surface US-SP (e.g., the top surface or the bottom surface) with a great surface area size. The thickness tsp of the plate-shaped scatterer MSP may correspond to a vertical dimension in a direction perpendicular to the surface (e.g., the top surface or the bottom surface) with the great surface area.

In the plate-shaped scatterer MSP according to one embodiment, a ratio of the maximum width W_{SP} in a plan view and the thickness tsp may be in a range of about 2:1 to about 10:1. The maximum width W_{SP} may be in a range of about 5 nm to about 300 nm, and the thickness tsp may be in a range of about 1 nm to about 50 nm.

The plate-shaped scatterer MSP according to one embodiment may have a small thickness equal to or smaller than about 50 nm, so that a ratio at which light incident in the thickness direction passes through the plate-shaped scatterer MSP and is emitted may be high. In other words, the plate-shaped scatterer MSP may have a small thickness equal to or smaller than tens of nanometers, thereby increasing a transmittance of the light through the plate-shaped scatterer MSP to increase a light transmittance of the optical layer containing the plate-shaped scatterer MSP.

In the plate-shaped scatterer MSP, the surface US-SP with the great surface area may have a polygonal shape in a plan view. Referring to FIG. 7A, the plate-shaped scatterer MSP may have a hexagonal shape in a plan view. However, the disclosure is not limited thereto, and the plate-shaped scatterer MSP may have any shape without restrictions in a plan view as long as it has the plate-shaped shape with the maximum width in a plan view significantly greater than the thickness.

FIG. 7B is an enlarged view of area “AA” in FIG. 7A. Referring to FIG. 7B, the plate-shaped scatterer MSP may include multiple metal hydroxide layers MOL1 to MOLn stacked in the thickness direction. Ionic ligands ATL may be disposed between the metal hydroxide layers MOL1 to MOLn to bind the neighboring metal hydroxide layers MOL1 to MOLn to each other. For example, in one embodiment, the plate-shaped scatterer MSP may include two or more metal hydroxide layers MOL1 to MOLn and anionic ligands disposed between the metal hydroxide layers MOL1 to MOLn. In one embodiment, the thickness tsp of the plate-shaped scatterer MSP may correspond to a total height in the direction in which the metal hydroxide layers MOL1 to MOLn are stacked.

Although FIG. 7B schematically shows each of the metal hydroxide layers MOL1 to MOLn as one layer, the disclosure is not limited thereto, and in another embodiment, multiple metal hydroxide units may be bonded to each other in each of the metal hydroxide layers MOL1 to MOLn.

Charges may be formed on the surface US-SP of the plate-shaped scatterer MSP. Accordingly, the plate-shaped scatterers MSP may not aggregate with each other and may be arranged to be spaced apart from each other at a regular spacing. Therefore, the plate-shaped scatterers MSP according to one embodiment may be dispersed in the base resin BR (FIG. 6), and thus, the source light may be evenly transmitted to the quantum dots QD-R and QD-G.

Referring again to FIGS. 5 and 6, the first light control part CCP-R may emit the red light by converting the wavelength of the source light provided from the display layer DP-ED. A portion of the source light may be emitted through the first light control part CCP-R without being converted in wavelength. The second light control part CCP-G may emit the green light by converting the wavelength of the source light provided from the display layer DP-ED. A portion of the source light may be emitted through the second light control part CCP-G without being converted in wavelength. In one embodiment, each of the first light control part CCP-R and the second light control part CCP-G may include quantum dots that convert the wavelength of at least a portion of the source light.

In one embodiment, the third light control part CCP-B may not contain quantum dots. However, the disclosure is not limited thereto, the third light control part CCP-B may also contain the quantum dots, and the third light control part CCP-B may emit light in a wavelength range different from wavelength ranges of the light of the first light control part CCP-R and the second light control part CCP-G.

In the light control layer CCL in one embodiment, the plate-shaped scatterers MSP may be contained in an amount in a range of about 0.1 wt % to about 20 wt % based on 100 wt % of a total weight of the light control parts CCP-R and CCP-G. In case that the plate-shaped scatterer MSP is contained in an amount smaller than 0.1 wt %, the dispersion effect of the source light may be reduced, and in case that the plate-shaped scatterer MSP is contained in an amount greater than 20 wt %, light absorption in the plate-shaped scatterer MSP may increase and the light transmittance may decrease.

In the light control layer CCL according to one embodiment, the first light control part CCP-R may contain first quantum dots, and the second light control part CCP-G may contain second quantum dots.

The first quantum dots QD-R may convert optical properties of at least a portion of the source light provided from the display layer DP-ED (FIG. 5). For example, the first quantum dots QD-R may convert a portion of the source light in a blue wavelength range into the red light. The first quantum dots QD-R, which convert the wavelength of the received light and emit the red light, may be called red quantum dots. In an embodiment, some of the first quantum dots QD-R may convert a portion in a green wavelength range of the source light into the red light.

The second quantum dots QD-G may be different from the first quantum dots QD-R. The second quantum dots QD-G may convert optical properties of at least a portion of the source light provided from the display layer DP-ED. For example, the second quantum dots QD-G may convert a portion of the source light in the blue wavelength range into the green light. The second quantum dots QD-G, which convert the wavelength of the received light and emit the green light, may be called green quantum dots.

The quantum dots contained in the light control layer CCL in one embodiment may be crystals of a semiconductor compound. Contents on the quantum dots to be described below may be applied to the first quantum dots QD-R and the second quantum dots QD-G.

The quantum dots may emit light with wavelengths depending on a size of the crystals. The quantum dots may emit light with various wavelengths by adjusting a ratio of elements in a quantum dot compound.

A diameter of the quantum dot may be, for example, in a range of about 1 nm to 10 nm. The quantum dots may be synthesized via a wet chemical process, a metal organic chemical vapor deposition process, a molecular beam epitaxy process, or similar processes.

Among the quantum dot producing processes, the wet chemical process may be a method of growing quantum dot particle crystals after mixing an organic solvent with a precursor material. When the quantum dot particle crystals grow, the organic solvent may naturally act as a dispersant coordinated to a quantum dot crystal surface and adjust the growth of the particle crystals. Therefore, the wet chemical process may be more readily performed than the vapor deposition method such as the metal organic chemical vapor deposition (MOCVD) or the molecular beam epitaxy (MBE), and may control the growth of the quantum dot particles with a low-cost process.

A core of the quantum dot may include a Group II-VI compound, a Group III-V compound, a Group III-VI compound, a Group I-III-VI compound, a Group IV-VI compound, a Group IV element, a Group IV compound, and combinations thereof.

The Group II-VI compound may be selected from a group consisting of a binary compound such as CdSe, CdTe, CdS, ZnS, ZnSe, ZnTe, ZnO, HgS, HgSe, HgTe, MgSe, MgS, and mixtures thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. In one embodiment, a Group II-VI semiconductor compound may further contain a Group I metal and/or a Group IV element. A Group I-II-VI compound may be selected from CuSnS or CuZnS, and a Group II-IV-VI compound may be selected from ZnSnS or the like. A Group I-II-IV-VI compound may be selected from a quaternary compound such as Cu₂ZnSnS₂, Cu₂ZnSnS₄, Cu₂ZnSnSe₄, Ag₂ZnSnS₂, and mixtures thereof.

The Group III-VI compound may include a binary compound such as In₂S₃, In₂Se₃, and the like, a ternary compound such as InGaS₃, InGaSe₃, and the like, or any combination thereof.

The Group I-III-VI compound may be selected from a ternary compound such as AgInS, AgInS₂, CuInS, CuInS₂, AgGaS₂, CuGaS₂, CuGaO₂, AgGaO₂, AgAlO₂, and mixtures thereof, or a quaternary compound such as AgInGaS₂, CuInGaS₂, and the like.

The Group III-V compound may be selected from a binary compound such as GaN, GaP, GaAs, GaSb, AlN, AlP, AlAs, AlSb, InN, InP, InAs, InSb, and mixtures thereof, a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In one embodiment, the group III-V compound may further contain a Group II metal. For example, InZnP or the like may be selected as the group III-II-V compound.

The group IV-VI compound may be selected from a group consisting of a binary compound such as SnS, SnSe, SnTe, PbS, PbSe, PbTe, and mixtures thereof; a ternary compound such as SnSeS, SnSeTe, SnSTe, PbSeS, PbSeTe, PbSTe, SnPbS, SnPbSe, SnPbTe, and mixtures thereof; and a quaternary compound such as SnPbSSe, SnPbSeTe, SnPbSTe, and mixtures thereof.

Examples of the group II-IV-V semiconductor compound may include a ternary compound such as ZnSnP, ZnSnP₂, ZnSnAs₂, ZnGeP₂, ZnGeAs₂, CdSnP₂, and CdGeP₂, and mixtures thereof.

The Group IV element may be selected from a group consisting of Si, Ge, and mixtures thereof. The Group IV compound may be a binary compound such as SiC, SiGe, and mixtures thereof.

Each element included in a multi-element compound such as the binary compound, the ternary compound, and the quaternary compound may exist in a particle at a uniform or non-uniform concentration. In other words, the Formula indicating the quantum dot refers to types of elements contained in the quantum dot compound, and the ratio of the elements in the compound may be different. For example, AgInGaS₂ may be described as AgInₓGa₁₋ₓS₂ (x is a real number between 0 and 1).

In this regard, the binary compound, the ternary compound, or the quaternary compound may exist in the particle at a uniform concentration, or may exist in a same particle with partially different concentration distributions. The quantum dots may have a core-shell structure in which one quantum dot surrounds another quantum dot. In the core-shell structure, there may be a concentration gradient in which a concentration of elements present in the shell decreases toward the core.

In some embodiments, the quantum dots may have a core-shell structure including a core containing the above-described nanocrystals and a shell surrounding the core. The shell of the quantum dot may serve as a protective layer to maintain semiconductor properties by preventing chemical denaturation of the core and/or as a charging layer to impart electrophoretic properties to the quantum dot. The shell may have a single layer or multi-layer structure. Examples of the shell of the quantum dot may include a metal or non-metal oxide, a semiconductor compound, or combinations thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO or a ternary compound such as MgAl₂O₄, CoFe₂O₄, NiFe₂O₄, and CoMn₂O₄, but the disclosure is not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but the disclosure is not limited thereto.

The quantum dot may have a full width of half maximum (FWHM) of a light emission wavelength spectrum equal to or smaller than about 45 nm. For example, the quantum dot may have a full width of half maximum (FWHM) of a light emission wavelength spectrum equal to or smaller than about 40 nm. For example, the quantum dot may have a full width of half maximum (FWHM) of a light emission wavelength spectrum equal to or smaller than about 30 nm. Within such range, color purity or color reproducibility may be improved. Because light emitted through such quantum dot is emitted in all directions, an optical viewing angle may be improved.

A shape of the quantum dot may not be particularly limited to those commonly used in the art, but may have shapes such as spherical, pyramidal, multi-arm, or cubic nano particles, nano tubes, nano wires, nano fibers, nano plate-shaped particles, and the like.

An energy band gap of the quantum dot may be adjusted by adjusting the size of the quantum dot or the ratio of the elements in the quantum dot compound, so that light with various wavelength ranges may be obtained from the layer containing the quantum dots. Therefore, the light control parts that emit the light with the various wavelengths may be implemented using the quantum dots as described above (the quantum dots of the different sizes or having the different element ratios in the quantum dot compound).

The light control layer CCL may include the third light control part CCP-B corresponding to the third pixel area PXA-B. The third light control part CCP-B may be a portion that transmits and emits the source light provided from the display layer DP-ED. The third light control part CCP-B may contain the base resin BR and the scatterers SP dispersed in the base resin BR. The third light control part CCP-B may not contain the quantum dots. However, the disclosure is not limited thereto, and the third light control part CCP-B may contain the quantum dots that convert a wavelength of a portion of the source light provided from the display layer DP-ED and emit the blue light.

In the light control layer CCL according to one embodiment, the third light control part CCP-B may contain spherical scatterers SP. The spherical scatterers SP may allow light incident on the third light control part CCP-B to be uniformly scattered, transmitted, and emitted. The spherical scatterer SP may have a spherical shape with a diameter of several hundred nanometers. For example, in one embodiment, a diameter of the spherical scatterer SP may be about 200 nm.

The spherical scatterer SP may be an inorganic particle. For example, the spherical scatterer SP may contain at least one of TiO₂, ZnO, Al₂O₃, SiO₂, and hollow silica. The spherical scatterer SP may contain one of TiO₂, ZnO, Al₂O₃, SiO₂, and the hollow silica, or may be a mixture of two or more selected from TiO₂, ZnO, Al₂O₃, SiO₂, and the hollow silica.

In the first to third light control parts CCP-R, CCP-G, and CCP-B, the base resin BR may be a medium in which the quantum dots QD-R and QD-G, the plate-shaped scatterers MSP, or the spherical scatterers SP are dispersed. The base resin BR may be made of a resin composition, which may generally be referred to as binders. For example, the base resin BR may be an acrylate-based resin, a urethane-based resin, a silicone-based resin, or an epoxy-based resin. The base resins BR respectively contained in the first to third light control parts CCP-R, CCP-G, and CCP-B may all be the same, or a base resin in at least one light control part may be different from base resins in the remaining light control parts.

In one embodiment, the plate-shaped scatterers MSP may not be aggregated with each other in each of the first light control part CCP-R and second light control part CCP-G and may be uniformly dispersed in the base resin BR. Accordingly, the plate-shaped scatterers MSP may evenly disperse the source light provided from the display layer DP-ED to the light control layer CCL in each of the light control parts CCP-R and CCP-G. Because of the small thickness of the plate-shaped scatterers MSP, the light that is transmitted without being used for the optical conversion may be emitted through the light control parts QD-R and QD-G with minimal light loss. For example, in case that the light-emitting element ED generates light in the blue wavelength range and the light in the green wavelength range and provides the generated light to the second light control part CCP-G, the light in the blue wavelength range may be transmitted to the second quantum dots QD-G and the second quantum dots QD-G may allow the green light to be emitted, and the light in the green light wavelength range may be transmitted through the plate-shaped scatterers MSP and emitted from the second light control part CCP-G. Accordingly, the light control layer CCL in one embodiment may exhibit high luminance as the transmittance of the source light is improved.

The light control layer CCL may be formed via inkjet printing. For example, each of the first light control part CCP-R, the second light control part CCP-G, and the third light control part CCP-B may be formed via a curing process after a corresponding light control part composition is supplied via a nozzle of an inkjet printing device. The plate-shaped scatterers MSP according to one embodiment may be provided in a uniformly dispersed state without agglomeration in the light control part composition. The method for forming the light control layer CCL is not limited thereto.

The light control layer CCL in one embodiment may exhibit the high luminance. The display device DD including the light control layer CCL in one embodiment may exhibit excellent frontal luminance, and may also exhibit excellent color quality because of high optical conversion efficiency of the quantum dots QD-R and QD-G in the light control layer CCL. For example, the display device DD in one embodiment containing the plate-shaped scatterers MSP according to one embodiment in the light control panel OP may exhibit excellent display quality based on the improved luminance and color characteristics.

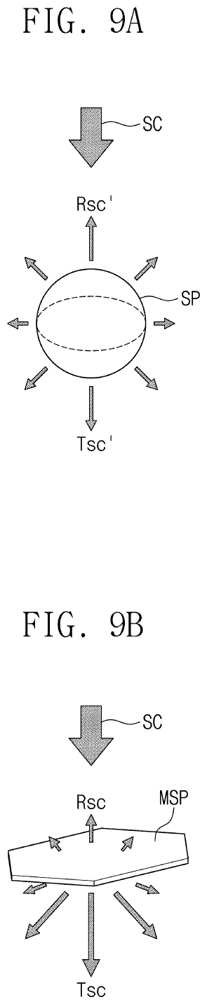

FIG. 8 is a schematic cross-sectional view showing a light control layer according to an embodiment. A light control layer CCL-a in one embodiment shown in FIG. 8 may contain the plate-shaped scatterer MSP in a third light control part CCP-Ba, which is a difference from the light control layer CCL in the embodiment shown in FIG. 6. For example, the light control layer CCL-a in one embodiment may contain the plate-shaped scatterer MSP in all of the first to third light control parts CCP-R, CCP-G, and CCP-Ba.

The first to third light control parts CCP-R, CCP-G, and CCP-Ba containing the plate-shaped scatterers MSP may scatter the source light provided from the display layer DP-ED (FIG. 5), and the source light may pass through the plate-shaped scatterers MSP and be emitted from the light control parts CCP-R, CCP-G, and CCP-Ba, resulting in higher light transmittance compared to an embodiment that the scatterers other than the plate-shaped scatterers are used. In particular, the light control layer CCL-a according to one embodiment may not contain the quantum dots and exhibit characteristics that light transmittance is increased in a forward direction that is the third direction DR3 in the third light control part CCP-Ba containing the plate-shaped scatterers MSP.

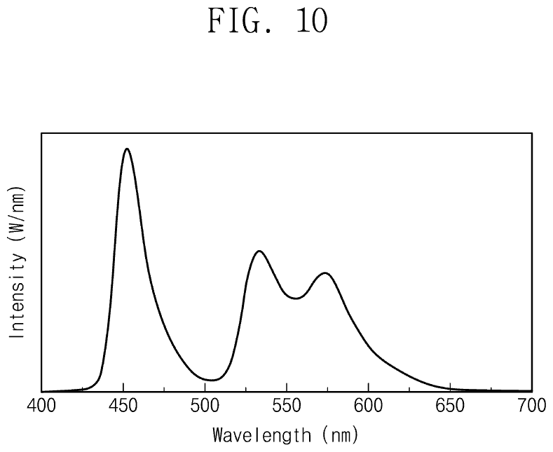

FIG. 9A shows light control characteristics in a spherical scatterer according to an embodiment. FIG. 9B shows light control characteristics in a plate-shaped scatterer according to an embodiment.

In case that source light SC is provided to the spherical scatterer SP, a portion of the provided light may become reflected or scattered light R_{SC}′, another portion of the provided light may pass through the spherical scatterer SP, still another portion of the provided light may be absorbed by the spherical scatterer SP, and only the remaining portion of the provided light may be transmitted and become transmitted light T_{SC}′. In the plate-shaped scatterer MSP according to one embodiment, a portion of the provided source light SC may become reflected or scattered light R_{SC}, another portion of the provided source light SC may pass through the plate-shaped scatterer MSP, and a portion of light transmitting the plate-shaped scatterer MSP may become transmitted light T_{SC}.

As the plate-shaped scatterer MSP according to one embodiment has the small thickness equal to or smaller than about 50 nm, a ratio of the transmitted light T_{SC} that is transmitted and emitted without being absorbed may be significantly increased compared to a ratio of the transmitted light T_{SC} of the spherical scatterer SP. Accordingly, in the optical functional layer containing the plate-shaped scatterers MSP, the light loss of the received light may be minimized, thereby increasing optical efficiency and the transmittance.

For example, in case that the light generated in the display layer DP-ED (FIG. 5) is emitted in the third direction DR3, which is the thickness direction, in the display device DD (FIG. 5) in one embodiment, in case that the plate-shaped scatterers MSP are contained in the light control panel OP (FIG. 5) disposed on the display layer DP-ED, the transmittance of the source light in the light control panel OP (FIG. 5) may increase because of the small thickness of the plate-shaped scatterer MSP. Even in case that the surface with the great width of the plate-shaped scatterer MSP is disposed in the direction parallel to the third direction DR3, the source light may be transmitted between the plate-shaped scatterers MSP because of the small thickness of the plate-shaped scatterer MSP. Because the plate-shaped scatterer MSP does not interfere with an optical path in the forward direction (e.g., the third direction DR3) of the source light, frontal luminance in the light control panel OP (FIG. 5) may be improved compared to an embodiment that other types of scatterers are used.

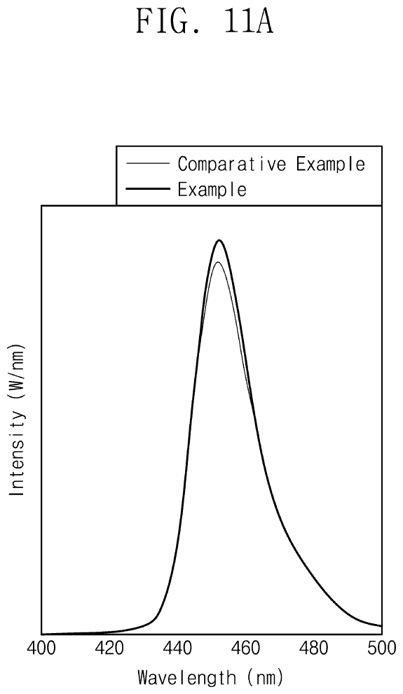

FIG. 10 shows a spectrum of source light provided from the display layer DP-ED (FIG. 5) of a display device according to an embodiment. FIG. 10 shows a spectrum of light output intensity based on wavelength.

Referring to FIG. 10, the source light may include a peak having a maximum intensity between about 450 nm and about 470 nm and a peak having a maximum intensity between about 520 nm and about 570 nm. For example, the source light provided from the display layer DP-ED (see FIG. 5) may contain the light in the blue wavelength range and the light in the green wavelength range. The light in the blue wavelength range may pass through the light control layer or may be provided to the quantum dots contained in the light control layer and light with a converted wavelength may be emitted. The light in the green wavelength range may also pass through the light control layer or may be provided to the quantum dots contained in the light control layer and light with a converted wavelength may be emitted.

On the other hand, in case that the source light containing the light in the green wavelength range is provided to the green light control part CCP-G (see FIG. 5), the light may be emitted through the green light control part CCP-G (FIG. 5).

For example, the display device according to one embodiment may include the light control part containing the plate-shaped scatterers in the main travel direction of the source light provided from the display layer to the light control layer to increase an amount of light emitted in the forward direction through the light control part, thereby improving the luminance of the display device. In particular, in the case of the display device in one embodiment including the display layer that provides the source light containing both the blue light and the green light, and the light control layer disposed on the display layer, at least the green light control part may contain the plate-shaped scatterers, so that an amount of green light passing through the green light control part and emitted may be increased. Accordingly, optical efficiency of the green pixel area may increase and thus the display quality of the display device may also be improved.

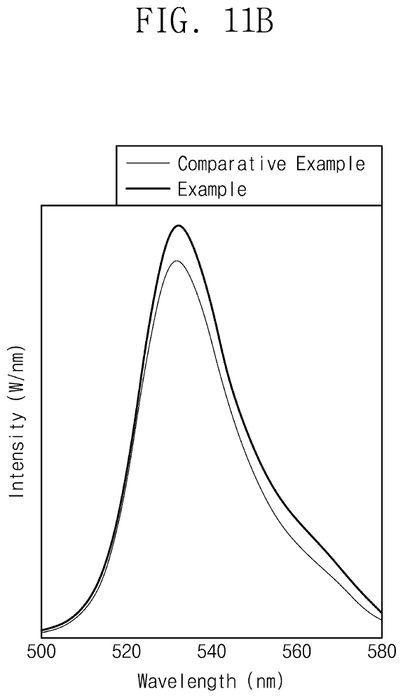

FIGS. 11A and 11B show results of evaluating characteristics of light control parts in Comparative Example and Example. FIG. 11A shows light output characteristics of blue light control parts in Comparative Example and Example, and FIG. 11B shows light output characteristics of green light control parts in Comparative Example and Example. In FIGS. 11A and 11B, a TiO₂ spherical scatterer was used in Comparative Example and a Mg₂Al(OH)₇ plate-shaped scatterer was used in Example. Light with the light output spectrum shown in FIG. 10 was used as source light to evaluate the luminance of the light control parts.

In FIG. 11A, Comparative Example is a blue light control part formed with the spherical scatterers in an amount of 6 wt % of a total light control part weight, and Examples is a blue light control part formed with the plate-shaped scatterers in an amount of 6 wt % of a total light control part weight. In FIG. 11B, Comparative Example is a green light control part formed with the spherical scatterers in an amount of 6 wt % of a total light control part weight and the green quantum dots in an amount of 40 wt % of the total light control part weight, and Example is a green light control part formed with the plate-shaped scatterers in an amount of 6 wt % of a total light control part weight and the green quantum dots in an amount of 40 wt % of the total light control part weight.

FIGS. 11A and 11B show intensity of light output from the light control parts, for example, frontal luminance in Comparative Example and Example. Referring to FIG. 11A, in the case of Example in which the blue light control part contains the plate-shaped scatterers, luminance was improved by 3% or more at a maximum light emission wavelength compared to Comparative Example containing the spherical scatterers. Referring to FIG. 11B, in the case of Example in which the green light control part contains the plate-shaped scatterers, luminance was improved by 13% or more at a maximum light emission wavelength compared to Comparative Example containing the spherical scatterers.

In other words, it may be seen that the light control parts containing the plate-shaped scatterers exhibit the improved luminance compared to the light control parts containing the spherical scatterers.

Referring to FIGS. 11A and 11B, it may be seen that the luminance improvement effect is greater in the green light control part than in the blue light control part. This is thought to be because the source light contains both the blue light and the green light, and as a result, a proportion of the green light emitted through the green light control part without being subjected to the optical conversion in the source light provided to the green light control part is increased.

For example, in case that the display device according to one embodiment includes the light in the green light wavelength range in addition to the blue light as the source light, in case that at least the green light control part contains the plate-shaped scatterers, the luminance of the display device may be improved. In case that the plate-shaped scatterers are additionally contained in the red light control part, the light that has passed through the red light control part without being absorbed at the plate-shaped scatterers may increase, and thus, a ratio of the green light provided to the red quantum dots in the source light may increase, thereby increasing the light conversion efficiency the light control layer. In case that the plate-shaped scatterers are additionally contained in the blue light control part, an amount of light that has passed through the blue light control part without being absorbed at the plate-shaped scatterers may increase, thereby also increasing the light transmittance of the blue light control part. Accordingly, in case that at least one of the light control parts distinguished from each other contains the plate-shaped scatterers, the display device in one embodiment may exhibit the improved luminance and the excellent display quality.

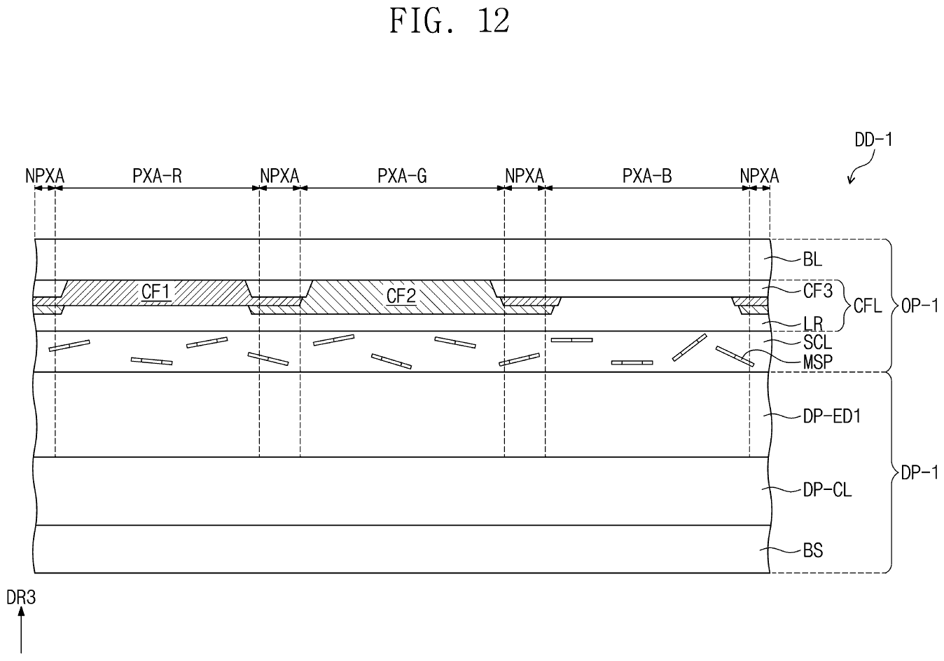

FIG. 12 is a schematic cross-sectional view of a display device in one embodiment. Hereinafter, in a description of a display device DD-1 in one embodiment shown in FIG. 12, content that duplicated with the content described with reference to FIGS. 1 to 11B will not be described again and differences will be described.

The display device DD-1 in one embodiment may include a display panel DP-1 and a light control panel OP-1 disposed on the display panel DP-1. The display panel DP-1 may emit source light provided to the light control panel OP-1.

The display panel DP-1 may include the base layer BS, the circuit layer DP-CL, and a display layer DP-ED1. The base layer BS may be a base member on which the circuit layer DP-CL and the display layer DP-ED1 are disposed. The circuit layer DP-CL may include a circuit element for driving the display layer DP-ED1. The source light may be emitted from the display layer DP-ED1. The display layer DP-ED1 may contain an organic electroluminescent light-emitting element ED (FIG. 5) as in the display device DD (FIG. 5) described above. In one embodiment, the display panel DP-1 may be an organic light-emitting display panel.

In an embodiment, the display panel DP-1 may be a liquid crystal display panel, a micro LED display panel, a nano LED display panel, a quantum dot light-emitting display panel, and the like. The liquid crystal display panel may include a liquid crystal element in the display layer DP-ED1, the micro LED display panel may include a micro light-emitting diode element that is an ultra-small light-emitting element in the display layer DP-ED1, the nano LED display panel may include a nano light-emitting diode element in the display layer DP-ED1, and the quantum dot light-emitting display panel may include a light-emitting element including quantum dots in the light-emitting layer. However, the types of display panel presented are examples, and any type of display panel may be used without limitation as long as it is the display panel DP-1 including the display layer DP-ED1 that may provide the source light.

For example, in one embodiment of the display device DD-1, the display panel DP-1 may include a display element that emits white light. Source light of the white light generated from the display panel DP-1 may be transmitted to the light control panel OP-1, and be controlled in the light control panel OP-1 and output as light respectively corresponding to the first to third pixel areas PXA-R, PXA-G, and PXA-B.

In one embodiment, the light control panel OP-1 may include a scattering layer SCL. The scattering layer SCL may contain the plate-shaped scatterers MSP according to one embodiment. In one embodiment, the scattering layer SCL may be a single common layer and may overlap an entirety of the first to third pixel areas PXA-R, PXA-G, and PXA-B and the peripheral area NPXA in the thickness direction DR3. However, the disclosure is not limited thereto, and the scattering layer SCL may be divided into portions respectively corresponding to the first to third pixel areas PXA-R, PXA-G, and PXA-B.

The scattering layer SCL may contain the plate-shaped scatterers MSP with the significantly smaller thickness compared to the width of the surface, thereby transmitting the source light while minimizing the light loss of the source light emitted from the display layer DP-ED1. The plate-shaped scatterers MSP contained in the scattering layer SCL may be made of layered double hydroxide and may be uniformly dispersed without agglomerating each other in the scattering layer SCL because of the charges contained on the surface, so that the source light may be uniformly dispersed and provided to the optical functional layer on top of the scattering layer SCL.

Accordingly, the display device DD-1 in one embodiment including the scattering layer SCL that contains the plate-shaped scatterers MSP according to one embodiment may exhibit the improved luminance.

The light control panel OP-1 of the display device DD-1 in one embodiment may further include the color filter layer CFL. The color filter layer CFL may include one or more color filters CF1, CF2, and CF3. In one embodiment, the first color filter CF1 may be the red filter that transmits the red light, the second color filter CF2 may be the green filter that transmits the green light, and the third color filter CF3 may be the blue filter that transmits the blue light. The color filter layer CFL may be disposed on the scattering layer SCL. In an embodiment, the color filter layer CFL may further include the low refractive index layer LR. The low refractive index layer LR may be disposed beneath the color filters CF1, CF2, and CF3.

Referring to FIG. 12, the scattering layer SCL may be disposed between the display layer DP-ED1 and the color filter layer CFL. In one embodiment, the scattering layer SCL may be disposed beneath the low refractive index layer LR. However, the disclosure is not limited thereto. In another embodiment, the low refractive index layer LR may be omitted, and the scattering layer SCL may be disposed directly beneath the color filters CF1, CF2, and CF3. In one embodiment, each of the color filters CF1, CF2, and CF3 may contain the plate-shaped scatterers MSP.

In one embodiment, the light control panel OP-1 of the display device DD-1 may include the light control layer disposed between the display layer DP-ED1 and the scattering layer SCL or between the scattering layer SCL and the color filter layer CFL and containing the quantum dots.

The display device in one embodiment may include the light control panel containing the plate-shaped scatterers, thereby exhibiting the excellent display quality because of the high light transmittance and the excellent dispersion characteristics of the plate-shaped scatterers. The display device in one embodiment may exhibit the improved luminance and the excellent color characteristics by containing the plate-shaped scatterers made of layered double hydroxide in at least one of the light control parts disposed on the display layer.

The display device in the embodiment may exhibit the improved luminance by increasing the transmittance and the scattering of the source light by containing the plate-shaped scatterers of layered double hydroxide in the shape of the nano plate.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display layer that provides source light; and
a light control layer disposed on the display layer and including a plurality of light control parts distinguished from each other,
wherein at least one of the plurality of light control parts includes quantum dots that convert a wavelength of the source light, and plate-shaped scatterers made of layered double hydroxide.

2. The display device of claim 1, wherein the plate-shaped scatterers have a ratio of a maximum width of a surface and a thickness in a range of about 2:1 to about 10:1.

3. The display device of claim 2, wherein
the maximum width is in a range of about 5 nm to about 300 nm, and
the thickness is in a range of about 1 nm to about 50 nm.

4. The display device of claim 1, wherein the layered double hydroxide is represented by Formula 1 below:
M²⁺_{X}M³⁺_{Y}(OH)_{(2X+3Y)} [Formula 1]
in the Formula 1,
M²⁺ is Zn, Co, Mg, Mn, Ni, or Fe,
M³⁺ is Fe, Co, Ni, Al, Ga, or In, and
X and Y are independent of each other and greater than 0.

5. The display device of claim 1, wherein the plate-shaped scatterers constitute in a range of about 0.1 wt % to about 20 wt % of a total weight 100 wt % of the plurality of light control parts including the plate-shaped scatterers.

6. The display device of claim 1, wherein the plurality of light control parts include:
a red light control part that emits red light and includes first quantum dots and the plate-shaped scatterers;
a green light control part that emits green light and includes second quantum dots and the plate-shaped scatterers; and
a blue light control part that transmits the source light.

7. The display device of claim 6, wherein the blue light control part includes spherical scatterers.

8. The display device of claim 6, wherein the blue light control part includes the plate-shaped scatterers.

9. The display device of claim 1, wherein the source light includes blue light and green light.

10. The display device of claim 1, wherein the display layer includes:
a first electrode;
a second electrode facing the first electrode; and
a light-emitting portion disposed between the first electrode and the second electrode, and including a light-emitting element that emits the source light.

11. A display device comprising:
a display panel that provides source light; and
a light control panel disposed on the display panel and including an optical scattering layer including plate-shaped scatterers made of layered double hydroxide.

12. The display device of claim 11, wherein
the plate-shaped scatterers have a ratio of a maximum width of a surface and a thickness in a range of about 2:1 to about 10:1,
the maximum width is in a range of about 5 nm to about 300 nm, and
the thickness is in a range of about 1 nm to about 50 nm.

13. The display device of claim 11, wherein the plate-shaped scatterers are represented by Formula 1 below:
M²⁺_{X}M³⁺_{Y}(OH)_{(2X+3Y)} [Formula 1]
in the Formula 1,
M²⁺ is Zn, Co, Mg, Mn, Ni, or Fe,
M³⁺ is Fe, Co, Ni, Al, Ga, or In, and
X and Y are independent of each other and greater than 0.

14. The display device of claim 11, wherein
the light control panel further includes a color filter layer disposed on the optical scattering layer and including a red filter, a green filter, and a blue filter, and
the source light is white light.

15. A display device divided into a first pixel area that emits red light, a second pixel area that emits green light, and a third pixel area that emits blue light on a plane, the display device comprising:
a display panel including a light-emitting element; and
a light control panel including a first light control part corresponding to the first pixel area, a second light control part corresponding to the second pixel area, and a third light control part corresponding to the third pixel area, wherein
the light control panel is disposed on the display panel,
the first light control part includes first quantum dots and plate-shaped scatterers,
the second light control part includes second quantum dots and the plate-shaped scatterers, and
the plate-shaped scatterers are made of layered double hydroxide.

16. The display device of claim 15, wherein
the plate-shaped scatterers have a ratio of a maximum width of a surface and a thickness in a range of about 2:1 to about 10:1,
the maximum width is in a range of about 5 nm to about 300 nm, and
the thickness is in a range of about 1 nm to about 50 nm.

17. The display device of claim 15, wherein the plate-shaped scatterers are represented by Formula 1 below:
M²⁺_{X}M³⁺_{Y}(OH)_{(2X+3Y)} [Formula 1]
in the Formula 1,
M²⁺ is Zn, Co, Mg, Mn, Ni, or Fe,
M³⁺ is Fe, Co, Ni, Al, Ga, or In, and
X and Y are independent of each other and greater than 0.

18. The display device of claim 15, wherein the third light control part includes spherical scatterers and does not include the plate-shaped scatterers.

19. The display device of claim 15, wherein the light-emitting element emits source light including the blue light and the green light.

20. The display device of claim 15, wherein
the light control panel further includes a color filter layer spaced apart from the display panel and disposed on the light control layer, and
the color filter layer includes a first color filter disposed corresponding to the first pixel area and transmits the red light, a second color filter disposed corresponding to the second pixel area and transmits the green light, and a third color filter disposed corresponding to the third pixel area and transmits the blue light.
